(19) United States
(12) Patent Application Publication
(10) Pub. No.: US 2024/0162379 A1
(43) Pub. Date: May 16, 2024

(54) SEMICONDUCTOR DEVICE AND MANUFACTURING METHOD THEREFOR

(71) Applicant: Enkris Semiconductor (Wuxi), Ltd., Wuxi (CN)

(72) Inventors: Weihua LIU, Wuxi (CN); Kai CHENG, Wuxi (CN)

(73) Assignee: Enkris Semiconductor (Wuxi), Ltd., Wuxi (CN)

(21) Appl. No.: 18/341,045

(22) Filed: Jun. 26, 2023

(30) Foreign Application Priority Data
Nov. 11, 2022 (CN) 202211412859.4

(51) Int. Cl. H01L 33/14; H01L 33/00; H01L 33/06; H01L 33/08; H01L 33/32

(52) U.S. Cl. CPC H01L 33/145; H01L 33/0075; H01L 33/06; H01L 33/08; H01L 33/325

(57) ABSTRACT

Disclosed are a semiconductor device and a manufacturing method therefor. The semiconductor device includes an n-type layer, a multiple quantum well layer, and a p-type ion doping layer which are disposed in sequence. The p-type ion doping layer includes an activation region and a passivation region, and the activation region is an oxygen doping region. By selectively activating the p-type ion doping layer, a passivation region at an edge of a light-emitting unit and a passivation region under the first electrode are formed, so that uniformity of luminous exitance of a device may be improved, and current crosstalk in the p-type layer may be avoided without etching and filling insulating medium or cutting isolation channels between the light-emitting units, thereby simplifying a manufacturing process of the device, and achieving a more uniform luminous exitance and higher light extraction rate of the semiconductor device.

### CROSS-REFERENCE TO RELATED APPLICATIONS

The disclosure claims priority to Chinese Patent Application CN202211412859.4, filed on Nov. 11, 2022, the entire contents of which are incorporated herein by reference.

### TECHNICAL FIELD

The present disclosure relates to the field of semiconductor technologies, and in particular, to a semiconductor device and a manufacturing method therefor.

### BACKGROUND

Nowadays, a light-emitting diode (LED) generally includes a substrate layer, a buffer layer, an n-type semiconductor layer, a multiple quantum well light-emitting layer and a p-type semiconductor layer.

Magnesium (Mg) is a most preferred dopant for the p-type semiconductor layers. A typical annealing temperature for conventional thermal annealing is within a temperature ranging from 600° C. to 900° C. to activate Mg ions. However, on the one hand, the current annealing method has low activation efficiency and may damage semiconductor materials, so that it is an urgent problem to find a simple way to activate Mg ions under low temperature. On the other hand, doping performed on p-type layers is difficult, and excessive Mg doped may also affect the material quality of the p-type semiconductor layers, leading to adverse consequences such as reduction of quantum efficiency, reduction of reliability, and shortened lifespan of light-emitting diode devices, thereby affecting efficiency of the light-emitting diodes.

### SUMMARY

In view of this, a semiconductor device and a manufacturing method therefor are provided by embodiments of the present disclosure to solve problems that a p-type semiconductor is difficult to activate and there is current leakage in the p-type semiconductor in the conventional art by selectively performing oxygen atom doping to a p-type ion doping layer.

According to an aspect of the present disclosure, a semiconductor device is provided, including:
a plurality of light-emitting units, where the plurality of light-emitting units include a substrate, an n-type layer disposed on the substrate, a multiple quantum well layer disposed on the n-type layer, and a p-type ion doping layer disposed on the multiple quantum well layer, the p-type ion doping layer includes an activation region and a passivation region, and the activation region is an oxygen doping region;
a first electrode, electrically connected to the p-type ion doping layer; and
a second electrode, electrically connected to the n-type layer.

As an optional embodiment, each of the plurality of light-emitting units includes an activation region, and activation regions of the plurality of light-emitting units are spaced on a plane parallel to the substrate.

As an optional embodiment, the passivation region includes a first passivation region and a second passivation region.

As an optional embodiment, the first passivation region is located in the p-type ion doping layer under the first electrode, and the second passivation region is located at an edge of each of the plurality of light-emitting units.

As an optional embodiment, a width of the first passivation region is equal from bottom to top, or changes in a mode including any one of linearly increasing, linearly decreasing, periodically changing, increasing first and then decreasing, increasing step by step, and decreasing step by step from bottom to top.

As an optional embodiment, p-type ions of the p-type ion doping layer include magnesium ions.

As an optional embodiment, a doping content of oxygen element in the activation region increases, decreases, or increases first and then decreases, in a direction away from the substrate.

As an optional embodiment, a doping content of oxygen element in the activation region is less than 1E21/cm³.

As an optional embodiment, a ratio of a doping content of oxygen element in the activation region to a doping content of p-type ions in the activation region is greater than 0.1 but less than 10.

As an optional embodiment, the semiconductor device further includes:
an Indium Tin Oxide (ITO) layer disposed on the p-type ion doping layer.

According to another aspect of the present disclosure, a manufacturing method for a semiconductor device is provided, including:
providing a substrate;
forming an n-type layer on the substrate and a multiple quantum well layer on the n-type layer;
forming a p-type ion doping layer on the multiple quantum well layer;
preparing a patterned mask layer on an upper surface of the p-type ion doping layer, where the mask layer forms a window;
forming, by implanting ionized oxygen-containing gas into the p-type ion doping layer under the window, an oxygen-doped activation region and a passivation region without oxygen ion implantation; and
preparing a first electrode and a second electrode, where the first electrode is electrically connected to the p-type ion doping layer, and the second electrode is electrically connected to the n-type layer.

As an optional embodiment, p-type ion doping layers to be activated on a plurality of light-emitting units are exposed through the patterned mask, a plurality of patterned activation regions are formed after the oxygen ion implantation, and the plurality of patterned activation regions are spaced on a plane parallel to the substrate.

As an optional embodiment, the passivation region includes a first passivation region and a second passivation region.

As an optional embodiment, the first passivation region is located in the p-type ion doping layer under the first electrode, and the second passivation region is located at an edge of each of the plurality of light-emitting units.

As an optional embodiment, p-type ions of the p-type ion doping layer include magnesium ions.

As an optional embodiment, a doping content of oxygen element in the activation region is controlled to increase, decrease, or increase first and then decrease in a direction away from the substrate, through a method of controlling energy of ion implantation.

As an optional embodiment, an ion implantation method includes a multiple implantation.

### BRIEF DESCRIPTION OF THE DRAWINGS

FIG. 1 is a schematic structural diagram of a semiconductor device according to an embodiment of the present disclosure.

FIG. 2 is a structural vertical view of a p-type ion doping layer of the semiconductor device according to FIG. 1.

FIG. 3(a) to FIG. 3(d) are schematic structural diagrams of a semiconductor device according to an embodiment of the present disclosure.

FIG. 4 is a flowchart of a manufacturing method for a semiconductor device according to an embodiment of the present disclosure.

FIG. 5 to FIG. 8 are decomposition schematic diagrams of structures of a semiconductor device during a preparation process according to an embodiment of the present disclosure.

FIG. 9 is a structural vertical view of the semiconductor structure according to FIG. 8.

### DETAILED DESCRIPTION OF THE EMBODIMENTS

Technical solutions in the embodiments of the disclosure will be clearly and completely described with reference to the accompanying drawings in the embodiments of the disclosure in the following description. Apparently, the described embodiments are only some, not all, embodiments of the present disclosure. Based on the embodiments in the present disclosure, all other embodiments obtained by those skilled in the art without making creative efforts fall in the protection scope of the present disclosure.

A light-emitting diode (LED) is a kind of semiconductor light-emitting device that can convert current into light within a specific wavelength range. The light-emitting diode is widely used as illuminants in the lighting field due to high brightness, low operating voltage, low power consumption, easy matching with integrated circuits, simple driving, and long lifespan.

The n-type semiconductor layer is used to provide electrons; the p-type semiconductor layer is used to provide holes. When current passes through, the electrons provided by the n-type semiconductor layer and the holes provided by the p-type semiconductor layer enter the multiple quantum well light-emitting layer to emit light through recombination luminescence.

To solve problems that a p-type semiconductor is difficult to activate and there is current leakage in the p-type semiconductor, a semiconductor device and a manufacturing method therefor are provided by the present disclosure. The semiconductor device includes an n-type layer, a multiple quantum well layer, and a p-type ion doping layer stacked in sequence. The p-type ion doping layer includes an activation region and a passivation region, and the activation region is an oxygen doping region. In the present disclosure, hydrogen in the p-type ion doping layer can be replaced by low-temperature annealing through a method of oxygen ion implantation, so that activation efficiency of the p-type ion doping layer may be improved. By selectively activating the p-type ion doping layer, a passivation region at an edge of a light-emitting unit and a passivation region under the first electrode are formed, so that uniformity of luminous exitance of a device may be improved, and current crosstalk in the p-type layer may be avoided without etching and filling insulating medium or cutting isolation channels between the light-emitting units, thereby simplifying a manufacturing process of the device, and achieving a more uniform luminous exitance and higher light extraction rate of the semiconductor device.

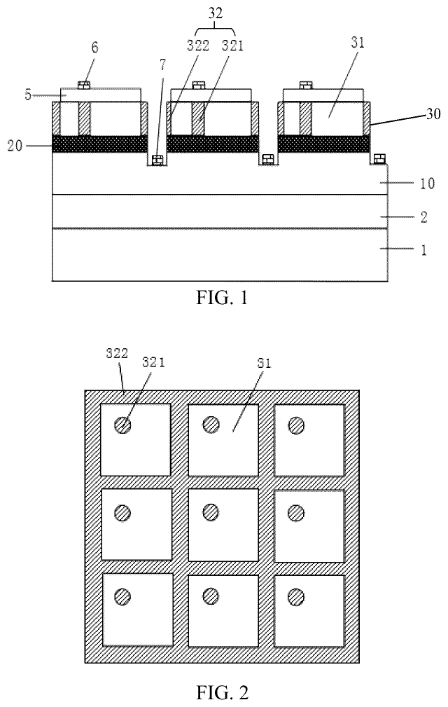

The semiconductor device and the manufacturing method therefor mentioned in the present disclosure will be further illustrated with reference to FIG. 1 to FIG. 9.

FIG. 1 is a schematic structural diagram of a semiconductor device according to an embodiment of the present disclosure. As shown in FIG. 1, the semiconductor device includes: a plurality of light-emitting units, where the plurality of light-emitting units include a substrate 1, an n-type layer 10 disposed on the substrate 1, a multiple quantum well layer 20 disposed on the n-type layer 10, and a p-type ion doping layer 30 disposed on the multiple quantum well layer 20, the p-type ion doping layer 30 includes an activation region 31 and a passivation region 32, and the activation region 31 is an oxygen doping region;
a first electrode 6, electrically connected to the p-type ion doping layer 30; and
a second electrode 7, electrically connected to the n-type layer 10.

Specifically, according to the device structure shown in FIG. 1, before preparing the second electrode 7, it is necessary to etch an area for the second electrode 7 on the p-type ion doping layer 30 and multiple quantum well layer 20 to expose the n-type layer 10 to prepare the second electrode 7 and finally, the device structure shown in FIG. 1 is formed.

In some embodiments, FIG. 2 is a structural vertical view of a p-type ion doping layer of the semiconductor device according to FIG. 1. As shown in FIG. 2, a plurality of light-emitting units are disposed on the same substrate, and each of the plurality of light-emitting units includes an activation region 31. Activation regions 31 on the plurality of light-emitting units are spaced on a plane parallel to the substrate 1. A plurality of p-type activation regions 31 may be obtained by selective activation on the same substrate at a time. The process is simple and efficient, which is conducive to batch preparation of the semiconductor light-emitting devices.

In some embodiments, the passivation region 32 includes a first passivation region 321 and a second passivation region 322, the first passivation region 321 is located in the p-type ion doping layer 30 under the first electrode 6, and the second passivation region 322 is located at an edge of each of the plurality of light-emitting units (as shown in FIG. 1). By setting the p-type ion doping layer 30 under the first electrode 6 as the first passivation region 321, light generated through carrier recombination in this region may be reduced and/or prevented. Generally, current density in an active area under an electrode is greater than that in the active area under a non electrode, which may result in uneven distribution of current density and affect light emitting efficiency of the light-emitting device. By setting the first passivation area 321 under the first electrode 6, the current density of the active area under the first electrode 6 is reduced, and uniformity of the current density distribution is improved, so that the light emitting efficiency of the light-emitting device may be improved. By setting the second passivation region 322 at the edge of each of the plurality of light-emitting units, unnecessary carrier recombination on a surface of the LED may be prevented, and the transverse leakage channel between adjacent light-emitting units may be cut off, so that the current leakage may be reduced, the uniformity of luminous exitance of the device may be improved, and the current crosstalk in the p-type layer may be avoided without etching and filling insulating medium or cutting isolation channels between the light-emitting units, thereby simplifying the device manufacturing process, and achieving more uniform luminous exitance and higher light extraction rate of the semiconductor device.

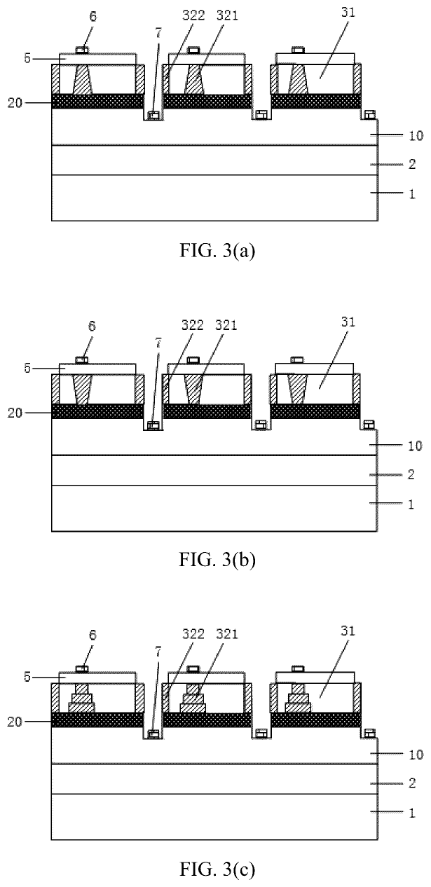

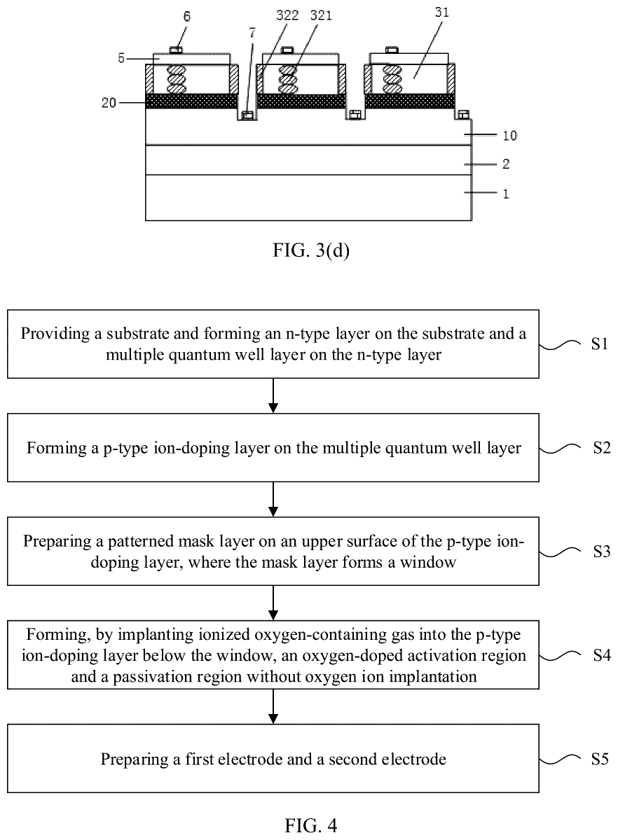

In some embodiments, FIG. 3(a) to FIG. 3(d) are schematic structural diagrams of a semiconductor device according to an embodiment of the present disclosure. A width of the first passivation region 321 is equal from bottom to top, or changes in a mode including any one of linearly increasing, linearly decreasing, periodically changing, increasing first and then decreasing, increasing step by step, and decreasing step by step from bottom to top. By designing the width of the first passivation region 321, current density in an active area under the first electrode 6 is further reduced, and current distribution is optimized, so that the light emitting efficiency of the light-emitting device may be improved.

In some embodiments, a doping content of oxygen element in the activation region 31 is less than 1E21/cm³ and a ratio of the doping content of the oxygen element in the activation region 31 to a doping content of p-type ions in the activation region 31 is greater than 0.1 but less than 10. By controlling the doping content of the oxygen element in the activation region 31, activation efficiency of p-type ions in the activation region 31 is controlled. The doping content of the oxygen element in the activation region 31 increases, decreases, or increases first and then decreases, in a direction away from the substrate 1. By controlling the doping content of the oxygen element in the activation region 31, a gradient of hole concentration in the activation region 31 is controlled. As an increase of local hole concentration and binding of local holes may increase hole recombination efficiency, the internal quantum efficiency of the light-emitting diode may be increased.

In some embodiments, a material of the substrate 1 may be any one of sapphire, silicon carbide, silicon, GaN, and diamond. To alleviate stress in an epitaxial structure above the substrate 1 and avoid cracking of the epitaxial structure, the semiconductor device may further include a buffer layer 2 prepared above the substrate 1. A material of the buffer layer 2 may include one or more of GaN, AlGaN, AlInGaN, and not limited to these. The semiconductor device may further include an ITO layer 5 prepared above the p-type ion doping layer 30, to achieve a purpose of simultaneously possessing transparency and ohmic contact resistance.

In some embodiments, materials of an n-type layer 10 and a p-type ion doping layer 30 are nitride semiconductors, and the materials of the n-type layer 10 and the p-type ion doping layer 30 may be the same or different. N-type ions in the n-type semiconductor layer 10 may be at least one of Si ions, Ge ions, Sn ions, Se ions, and Te ions. P-type doping ions in the p-type ion doping layer 30 may be Mg ions. A multiple quantum well layer 20 includes a barrier layer and a well layer. A band gap of the barrier layer is greater than a band gap of the well layer. For example, a material of the barrier layer is GaN, and a material of the well layer is InGaN.

In some embodiments, an oxygen element may be used to form oxygen-hydrogen bonds with a hydrogen element in the p-type ion doping layer 30, so that magnesium-hydrogen bonds may be broke and magnesium ions are released, achieving p-type activation of the p-type ion doping layer 30 and forming the activation region 31. Therefore, a quantity of the magnesium-hydrogen bonds in the activation region 31 is lower than that in the passivation region 32. The magnesium ions in the activation region 31 are released and activated to generate holes, while the magnesium ions in the passivation region 32 are not released and activated without holes generated.

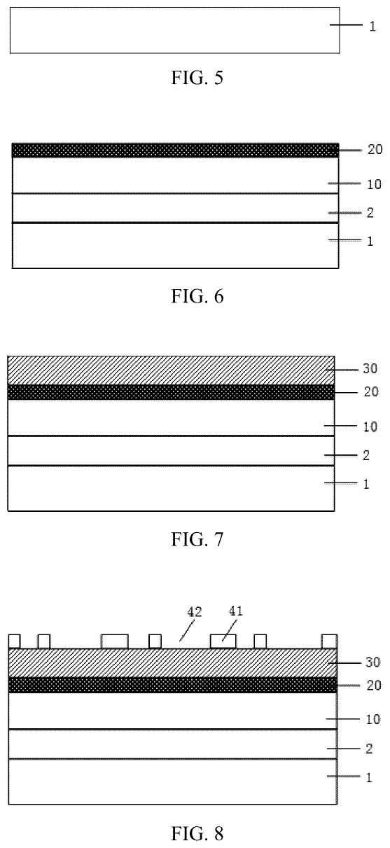

According to another aspect of the present disclosure, FIG. 4 is a flowchart of a manufacturing method for a semiconductor device according to an embodiment of the present disclosure. FIG. 5 to FIG. 8 are decomposition schematic diagrams of structures of a semiconductor device during a preparation process according to an embodiment of the present disclosure. As shown in FIG. 4, the manufacturing method for the semiconductor device is provided by an embodiment of the present disclosure, and the method includes the following steps.

As shown in FIG. 5 and FIG. 6, Step S1: providing a substrate, and forming an n-type layer on the substrate and a multiple quantum well layer on the n-type layer. A material of the substrate 1 may be any one of sapphire, silicon carbide, silicon, GaN, and diamond. In some embodiments, before the n-type layer 10 is prepared, a buffer layer 2 may also be prepared on the substrate 1. The functions and components of the buffer layer 2, the n-type layer 10, and the multiple quantum well layer 20 have been described above and will not be described herein again.

As shown in FIG. 7, Step S2: forming a p-type ion doping layer on the multiple quantum well layer. Methods for forming the p-type ion doping layer 30 include: atomic layer deposition (ALD), chemical vapor deposition (CVD), molecular beam epitaxy (MBE), plasma enhanced chemical vapor deposition (PECVD), low pressure chemical vapor deposition (LPCVD), metal organic chemical vapor deposition (MOCVD), or a combination thereof. It should be understood that the methods described herein to form the p-type ion doping layer 30 is only for example, and any method known to those skilled in the art can be used to form the p-type ion doping layer 30 in the present disclosure.

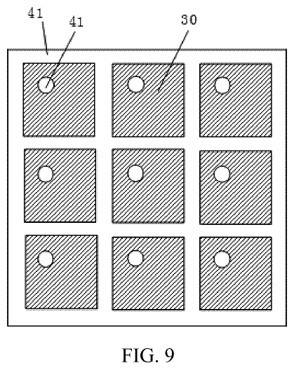

As shown in FIG. 8, Step S3: preparing a patterned mask layer on a surface of the p-type ion doping layer, where the mask layer forms a window.

Step S4: forming, by implanting ionized oxygen-containing gas into the p-type ion doping layer under the window, an oxygen-doped activation region and a passivation region (as shown in FIG. 1) without oxygen ion implantation. Through selective activation, a passivation region at an edge of the light-emitting unit and a passivation region under a first electrode 6 are formed, so that current leakage of the p-type layer may be reduced and light emitting efficiency of the device may be improved. In some embodiments, after preparing the activation region 31 and the passivation region 32, an ITO layer 5 may be further prepared above the p-type ion doping layer 30, to achieve a purpose of simultaneously possessing transparency and ohmic contact resistance.

It should be noted that in Step S4, after implanting ionized oxygen-containing gas into the p-type ion doping layer 30 under the window 42, an annealing operation is required to complete the activation of the activation region 31. In the conventional art, annealing operation for a magnesium-doped GaN layer should be performed under high temperature conditions to cut off junctions of Mg—H complexes, thereby achieving p-type activation. However, when the the annealing operation is performed on the GaN layer under a high temperature, nitrogen is easy to be removed from the GaN layer. Through the nitrogen removal, donor type defects may be generated in the GaN layer, thereby damaging the device performance of the semiconductor structure. However, oxygen-hydrogen bonds have stronger ion bonding energy compared with magnesium-hydrogen bonds. Therefore, after oxygen ions are implanted into material, the junctions of the Mg—H complexes can be cut off under low temperature conditions, thereby achieving p-type activation of Mg-doped GaN. The ion implanting method includes a multiple implantation, through which activation efficiency of the activation region 31 may be improved.

Step S5: preparing a first electrode and a second electrode.

The first electrode is electrically connected to the p-type ion doping layer, and the second electrode is electrically connected to the n-type layer.

In some embodiments, FIG. 9 is a structural vertical view of the semiconductor structure according to FIG. 8. A plurality of patterned p-type ion doping layers 30 to be activated may be exposed on the same substrate through a patterned mask layer 41. A plurality of p-type activation regions 31 may be obtained by selective activation on the same substrate at a time. The plurality of patterned activation regions 31 are spaced on a plane parallel to the substrate 1, and the process is simple and efficient, which is conducive to the batch preparation of semiconductor light-emitting devices.

In some embodiments, the passivation region 32 includes a first passivation region 321 and a second passivation region 322, the first passivation region 321 is located in the p-type ion doping layer 30 under the first electrode 6, and the second passivation region 322 is located at an edge of each of the plurality of light-emitting units (as shown in FIG. 1). By setting the p-type ion doping layer 30 under the first electrode 6 as the first passivation region 321, light generated through carrier recombination in this region may be reduced and/or prevented. Generally, current density in an active area under an electrode is greater than that in the active area under a non electrode, which may result in uneven distribution of current density and affect light emitting efficiency of the light-emitting device. By setting the first passivation area 321 under the first electrode 6, the current density of the active area under the first electrode 6 is reduced, and uniformity of the current density distribution is improved, so that the light emitting efficiency of the light-emitting device may be improved. By setting the second passivation region 322 at the edge of each of the plurality of light-emitting units, unnecessary carrier recombination on a surface of the LED may be prevented, and the transverse leakage channel between adjacent light-emitting units may be cut off, so that the current leakage may be reduced, the uniformity of luminous exitance of the device may be improved, and the current crosstalk in the p-type layer may be avoided without etching and filling insulating medium or cutting isolation channels between the light-emitting units, thereby simplifying the device manufacturing process, and achieving more uniform luminous exitance and higher light extraction rate of the semiconductor device.

In some embodiments, FIGS. 3(a) to 3(d) are schematic structural diagrams of a semiconductor device according to an embodiment of the present disclosure. A width of the first passivation region 321 is equal from bottom to top, or changes in a mode including any one of linearly increasing, linearly decreasing, periodically changing, increasing first and then decreasing, increasing step by step, and decreasing step by step from bottom to top. By designing the width of the first passivation region 321, current density in an active area under the first electrode 6 is further reduced, and current distribution is optimized, so that the light emitting efficiency of the light-emitting device may be improved.

In some embodiments, a doping content of oxygen element in the activation region 31 is less than 1E21/cm³ and a ratio of the doping content of the oxygen element in the activation region 31 to a doping content of p-type ions in the activation region 31 is greater than 0.1 but less than 10. By controlling the doping content of the oxygen element in the activation region 31, activation efficiency of p-type ions in the activation region 31 is controlled. The doping content of the oxygen element in the activation region 31 increases, decreases, or increases first and then decreases, in a direction away from the substrate 1. By controlling energy for ion implantation or conducting multiple ion implantation, a gradient of hole concentration in the activation region 31 is controlled, so that the gradient of hole concentration in the activation region 31 is controlled. As an increase of local hole concentration and binding of local holes may increase hole recombination efficiency, the internal quantum efficiency of the light-emitting diode may be increased.

In some embodiments, an oxygen element may be used to form oxygen-hydrogen bonds with a hydrogen element in the p-type ion doping layer 30, so that magnesium-hydrogen bonds may be broke and magnesium ions are released, achieving p-type activation of the p-type ion doping layer 30 and forming the activation region 31. Therefore, a quantity of the magnesium-hydrogen bonds in the activation region 31 is lower than that in the passivation region 32. The magnesium ions in the activation region 31 are released and activated to generate holes, while the magnesium ions in the passivation region 32 are not released and activated without holes generated.

A semiconductor device and a manufacturing method therefor are provided by the present disclosure. The semiconductor device includes an n-type layer, a multiple quantum well layer, and a p-type ion doping layer which are stacked in sequence. The p-type ion doping layer includes an activation region and a passivation region, and the activation region is an oxygen doping region. In the present disclosure, hydrogen in the p-type ion doping layer can be replaced by low-temperature annealing through a method of oxygen ion implantation, so that activation efficiency of the p-type ion doping layer may be improved. By selectively activating the p-type ion doping layer, a passivation region at an edge of a light-emitting unit and a passivation region under the first electrode are formed, so that uniformity of luminous exitance of a device may be improved, and current crosstalk in the p-type layer may be avoided without etching and filling insulating medium or cutting isolation channels between the light-emitting units, thereby simplifying a manufacturing process of the device, and achieving a more uniform luminous exitance and higher light extraction rate of the semiconductor device.

It should be understood that the term “including” and its variations used in the present disclosure are open-ended, that is, “including but not limited to”. The term “one embodiment” means “at least one embodiment”, the term “another embodiment” means “at least one other embodiment”. In this specification, the schematic expressions of the above terms do not necessarily refer to the same embodiments or examples. Moreover, the specific features, structures, materials, or characteristics described can be combined in an appropriate manner in any one or more embodiments or examples. In addition, those skilled in the art may combine and permutation the different embodiments or examples described in this specification, as well as the features of different embodiments or examples, without contradiction.

The above-mentioned embodiments are only the preferred embodiments of the present disclosure, and not intended to limit the protection scope of the present disclosure. Any modification, equivalent replacement, improvement and so on that made in the spirit and principle of the present disclosure shall fall into the protection scope of the present disclosure.

What is claimed is:

1. A semiconductor device, comprising:
a plurality of light-emitting units, wherein the plurality of light-emitting units comprise a substrate, an n-type layer disposed on the substrate, a multiple quantum well layer disposed on the n-type layer, and a p-type ion doping layer disposed on the multiple quantum well layer, the p-type ion doping layer comprises an activation region and a passivation region, and the activation region is an oxygen doping region;
a first electrode, electrically connected to the p-type ion doping layer; and
a second electrode, electrically connected to the n-type layer.

2. The semiconductor device according to claim 1, wherein each of the plurality of light-emitting units comprises an activation region, and activation regions of the plurality of light-emitting units are spaced on a plane parallel to the substrate.

3. The semiconductor device according to claim 1, wherein the passivation region comprises a first passivation region and a second passivation region.

4. The semiconductor device according to claim 3, wherein the first passivation region is located in the p-type ion doping layer under the first electrode, and the second passivation region is located at an edge of each of the plurality of light-emitting units.

5. The semiconductor device according to claim 3, wherein a width of the first passivation region is equal from bottom to top, or changes in a mode comprising any one of linearly increasing, linearly decreasing, periodically changing, increasing first and then decreasing, increasing step by step, and decreasing step by step from bottom to top.

6. The semiconductor device according to claim 1, wherein p-type ions of the p-type ion doping layer comprise magnesium ions.

7. The semiconductor device according to claim 1, wherein a doping content of oxygen element in the activation region increases, decreases, or increases first and then decreases, in a direction away from the substrate.

8. The semiconductor device according to claim 1, wherein a doping content of oxygen element in the activation region is less than 1E21/cm³.

9. The semiconductor device according to claim 1, wherein a ratio of a doping content of oxygen element in the activation region to a doping content of p-type ions in the activation region is greater than 0.1 but less than 10.

10. The semiconductor device according to claim 1, wherein the semiconductor device further comprises:
an Indium Tin Oxide (ITO) layer disposed on the p-type ion doping layer.

11. A manufacturing method for a semiconductor device, comprising:
providing a substrate;
forming an n-type layer on the substrate and a multiple quantum well layer on the n-type layer;
forming a p-type ion doping layer on the multiple quantum well layer;
preparing a patterned mask layer on an upper surface of the p-type ion doping layer, wherein the mask layer forms a window;
forming, by implanting ionized oxygen-containing gas into the p-type ion doping layer under the window, an oxygen-doped activation region and a passivation region without oxygen ion implantation; and
preparing a first electrode and a second electrode, wherein the first electrode is electrically connected to the p-type ion doping layer, and the second electrode is electrically connected to the n-type layer.

12. The method according to claim 11, wherein p-type ion doping layers to be activated on a plurality of light-emitting units are exposed through the patterned mask, a plurality of patterned activation regions are formed after the oxygen ion implantation, and the plurality of patterned activation regions are spaced on a plane parallel to the substrate.

13. The method according to claim 11, wherein the passivation region comprises a first passivation region and a second passivation region.

14. The method according to claim 13, wherein the first passivation region is located in the p-type ion doping layer under the first electrode, and the second passivation region is located at an edge of each of the plurality of light-emitting units.

15. The method according to claim 11, wherein p-type ions of the p-type ion doping layer comprise magnesium ions.

16. The method according to claim 11, wherein a doping content of oxygen element in the activation region is controlled to increase, decrease, or increase first and then decrease in a direction away from the substrate, through a method of controlling energy of ion implantation.

17. The method according to claim 11, wherein an ion implantation method comprises a multiple implantation.
